(19) United States
(12) Patent Application Publication
(10) Pub. No.: US 2025/0087447 A1
(43) Pub. Date: Mar. 13, 2025

(54) Charged Particle Beam Apparatus and Sample Analysis Method

(71) Applicant: Hitachi High-Tech Corporation, Minato-ku, Tokyo (JP)

(72) Inventors: Yuya SUZUKI, Tokyo (JP); Kuniyasu NAKAMURA, Tokyo (JP)

(21) Appl. No.: 18/292,640

(22) PCT Filed: Jul. 28, 2021
(86) PCT No.: PCT/JP2021/027878

§ 371 Date: Jan. 26, 2024

(51) Int. Cl. H01J 37/244; H01J 37/20; H01J 37/252

(52) U.S. Cl. CPC H01J 37/244; H01J 37/20; H01J 37/252

(57) ABSTRACT

A charged particle beam apparatus includes: a lens barrel 2; an electron gun 3 configured to emit an electron beam EB1; a stage 40; a transport port 20 provided to transport a sample stage 30 on which a sample SAM is mounted; and a plurality of X-ray detectors 50 configured to detect an X-ray. The stage 40 includes a mounting portion 40c that is provided below the electron gun 3 in the lens barrel 2. The mounting portion 40c includes at least an opening portion OP that is formed to open on an optical axis OA. When the sample stage 30 is mounted on the mounting portion 40c, the sample SAM is positioned in the opening portion OP to be positioned on the optical axis OA. A moving mechanism 51 is electrically connected to an X-ray detector 50a closest to the transport port 20. The X-ray detector 50a is movable by the moving mechanism 51 in a direction toward or away from the mounting portion 40c. A position of the X-ray detector 50a when the X-ray detector 50a is moved closest to the mounting portion 40c overlaps a transport path 32 in a plan view.

### TECHNICAL FIELD

The present invention relates to a charged particle beam apparatus and a sample analysis method, and particularly relates to a charged particle beam apparatus including a plurality of X-ray detectors and a sample analysis method using the charged particle beam apparatus.

### BACKGROUND ART

Recently, miniaturization of a semiconductor device has progressed. In particular, in a semiconductor device having a steric structure, high integration and high capacity have progressed dramatically by combination with a stacking technique. As a charged particle beam apparatus for analyzing the semiconductor device, for example, a scanning electron microscope (SEM), a transmission electron microscope (TEM), or a scanning transmission electron microscope (STEM) is used. When the analysis is executed by the apparatus, a sample to be analyzed needs to be provided between an upper objective lens and a lower objective lens.

In addition, as a method of analyzing elements in a sample, energy dispersive X-ray spectrometry (EDX) is known. In this method, by emitting an electron beam to a sample, a characteristic X-ray generated from the sample is detected by an X-ray detector, and composition analysis of the sample is executed from the detected characteristic X-ray. The above-described charged particle beam apparatus includes the X-ray detector.

On the other hand, in the TEM among the charged particle beam apparatuses, a side entry type is generally used. In this type, a sample is placed at a tip of a sample holder, and the sample holder is inserted into a lens barrel. As a result, the sample is provided between an upper objective lens and a lower objective lens from a direction perpendicular to an optical axis. A field of view that is analyzed using a driving mechanism for a stage provided on the atmosphere side (the outside of the lens barrel) is determined to execute the EDX analysis.

PTL 1 discloses a side entry type TEM, and this TEM includes a plurality of X-ray detectors. In addition, each of the plurality of X-ray detectors is movable in a direction toward or away from a sample.

### CITATION LIST

### Patent Literature

PTL 1: JP2017-91652A

### SUMMARY OF INVENTION

### Technical Problem

In the side entry type, the sample holder is inserted into the lens barrel of the charged particle beam apparatus. Therefore, a portion on a vacuum side and a portion on an atmospheric pressure side are present in the sample holder. Accordingly, the portion on the atmospheric pressure side is likely to be affected by an air pressure variation, a sonic wave, and the like, and displacement of the field of view may occur due to the effect thereof. Therefore, a certain degree of rigidity is required for the sample holder. Therefore, it is difficult to reduce the size of the sample holder.

On the other hand, in the EDX analysis, performance such as high speed, high resolution, and high sensitivity is required. Therefore, a technique of increasing the area of a detection element (sensor) provided in the X-ray detector, a technique of mounting a plurality of sensors on the X-ray detector, and the like have been developed. Here, in the side entry type, the sample holder is also used to move the field of view to be analyzed. Accordingly, in a space where the sample holder is present, an X-ray cannot be used for the EDX analysis. That is, in the space where the sample holder is present, the X-ray detector cannot be provided. Therefore, it may be difficult to execute a method such as a method of increasing the number of X-ray detectors or a method of moving the X-ray detector toward a sample.

A main object of the present application is to improve performance such as high speed, high resolution, and high sensitivity required for detecting an X-ray. Other objects and new characteristics will be clarified with reference to description of the specification and the accompanying drawings.

### Solution to Problem

The summary of a representative embodiment disclosed in the present application will be simply described as follows.

A charged particle beam apparatus according to one embodiment includes: a lens barrel; an electron gun configured to emit an electron beam and provided in the lens barrel; a stage provided in the lens barrel; a transport port provided in the lens barrel to transport a sample stage on which a sample is mounted from an outside to an inside of the lens barrel or from the inside to the outside of the lens barrel; and a plurality of X-ray detectors configured to detect an X-ray and provided in the lens barrel. The stage includes a mounting portion that is provided to mount the sample stage and is provided below the electron gun in the lens barrel, the mounting portion includes at least an opening portion that is formed to open on an optical axis, when the sample stage is mounted on the mounting portion, the sample is positioned in the opening portion to be positioned on the optical axis, a moving mechanism is electrically connected to a first X-ray detector closest to the transport port among the plurality of X-ray detectors, the first X-ray detector is movable by the moving mechanism in a direction toward or away from the mounting portion, and a position of the first X-ray detector when the first X-ray detector is moved closest to the mounting portion overlaps a transport path through which the sample stage passes from the transport port to the mounting portion in a plan view.

### Advantageous Effects of Invention

According to one embodiment, a charged particle beam apparatus capable of improving performance required for detecting an X-ray can be provided.

### BRIEF DESCRIPTION OF DRAWINGS

FIG. 1 is a schematic diagram illustrating one example of a charged particle beam apparatus according to a first embodiment.

FIG. 2 is a plan view illustrating a stage and a plurality of X-ray detectors in the first embodiment.

FIG. 3 is a plan view illustrating the stage in the first embodiment.

FIG. 4A is a cross-sectional view illustrating the stage in the first embodiment.

FIG. 4B is a cross-sectional view illustrating the details of an objective lens in the first embodiment.

FIG. 4C is a cross-sectional view illustrating a modification example of the stage in the first embodiment.

FIG. 5 is a cross-sectional view illustrating the X-ray detectors in the first embodiment.

FIG. 6 is a plan view illustrating a part of a sample analysis method according to the first embodiment.

FIG. 7 is a plan view following FIG. 6 and illustrating the sample analysis method.

FIG. 8 is a plan view following FIG. 7 and illustrating the sample analysis method.

FIG. 9 is a plan view illustrating a stage and a plurality of X-ray detectors in a first modification example.

FIG. 10 is a plan view illustrating a stage and a plurality of X-ray detectors in a second modification example.

FIG. 11 is a flowchart illustrating the sample analysis method according to the first embodiment.

### DESCRIPTION OF EMBODIMENTS

Hereinafter, an embodiment will be described in detail based on the drawings. In all the diagrams for describing the embodiment, members having the same functions are represented by the same reference numerals, and the description thereof will not be repeated. In addition, in the following embodiment, basically, the description of the same or identical portions will not be repeated unless particularly necessary.

In addition, an X direction, a Y direction, and a Z direction described in the present application intersect each other and are orthogonal to each other. In the present application, the Z direction will be described as a vertical direction, a height direction, or a thickness direction of a structure. In addition, the expression “plan view” used in the present application represents that a surface configured by the X direction and the Y direction is “plane” and this “plane” is seen from the Z direction. In addition, it can be said that this “plane” is a surface perpendicular to an optical axis OA of a charged particle beam apparatus 1.

### First Embodiment

### <Structure of Charged Particle Beam Apparatus 1>

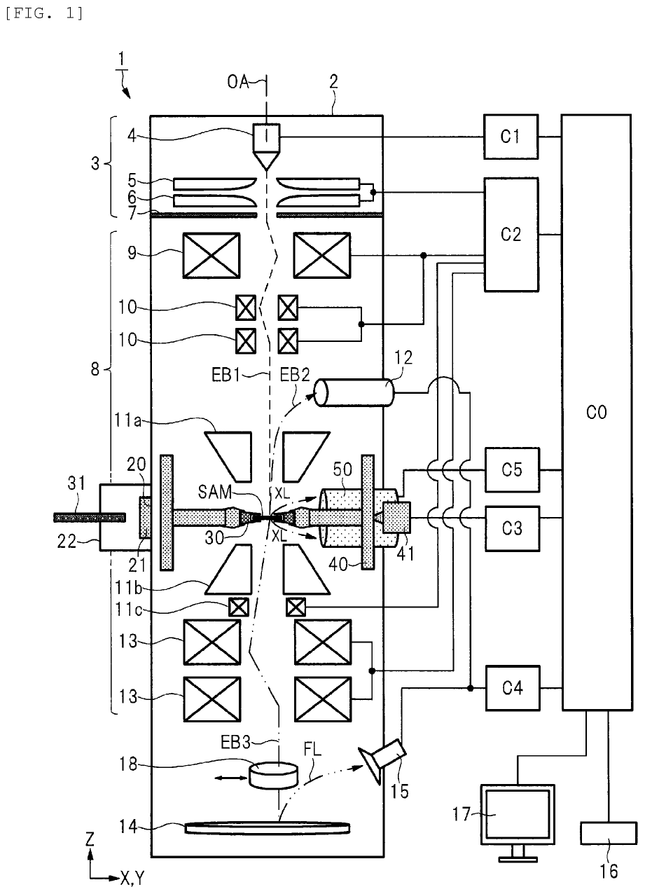

Hereinafter, the charged particle beam apparatus 1 according to a first embodiment will be described using FIG. 1. In the first embodiment, a side entry type transmission electron microscope (TEM) is described as an example of the charged particle beam apparatus 1. The charged particle beam apparatus 1 may be a scanning transmission electron microscope (STEM) and may include a STEM detector 18 that can be inserted into and retracted from the optical axis OA.

The charged particle beam apparatus 1 includes a lens barrel 2 having a cylindrical shape. An inside of the lens barrel 2 is mainly equipped with an electron gun 3 that can emit an electron beam (charged particle beam) EB1, an electron optical system 8, a detector 12, a fluorescent screen 14, a camera 15, a stage 40, and X-ray detectors 50.

The inside of the lens barrel 2 can be maintained in a vacuum state using a vacuum evacuation means (not illustrated). “Vacuum state” described in the present application represents a state where the internal pressure of the lens barrel 2 is lower than the atmospheric pressure and is, for example, 1×10⁻² Pa or lower.

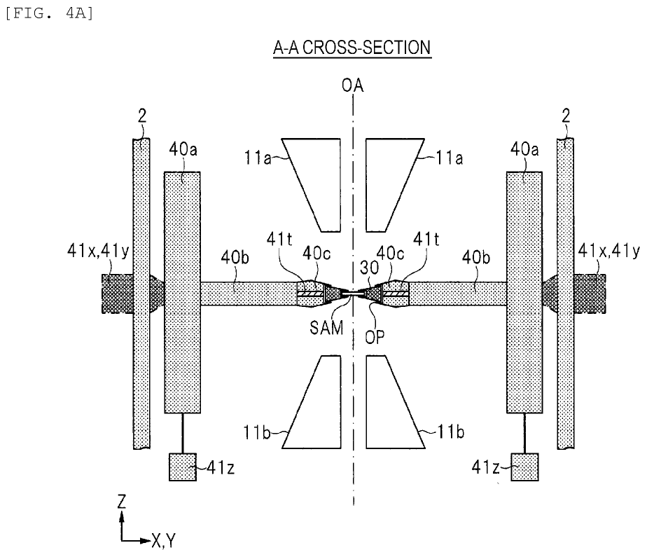

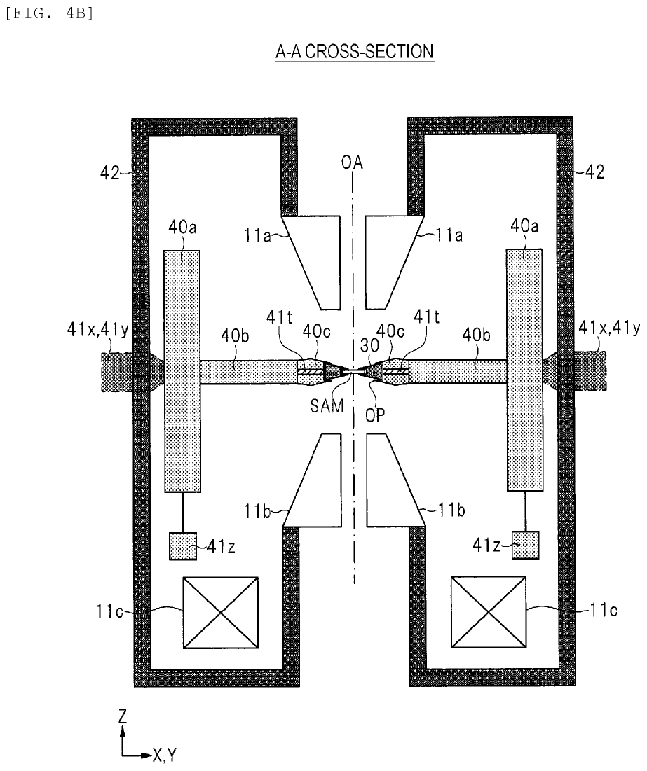

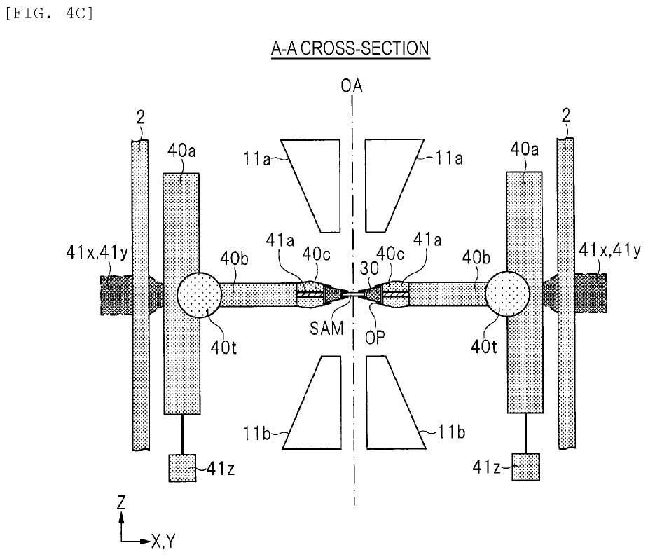

The electron gun 3 includes an electron source 4 that is an emission source of an electron beam EB1, a suppression electrode 5, an extraction electrode 6, and a positive electrode 7. The electron optical system 8 includes a focusing lens 9, a deflection lens 10, an upper magnetic pole 11a, a lower magnetic pole 11b, an objective lens coil 11c, and an imaging system 13. The stage 40 is provided below the electron gun 3, is provided between the upper magnetic pole 11a and the lower magnetic pole 11b, and is connected to the lens barrel 2. The imaging system 13 is configured by a projector lens or the like for imaging transmitted electrons EB3. The details of a relationship between the upper magnetic pole 11a, the lower magnetic pole 11b, and the objective lens coil 11c configuring an objective lens 11 will be described using FIG. 4B.

In addition, in the lens barrel 2, a transport port 20, a sample exchange chamber 22, and a gate valve 21 that executes an opening/closing operation are provided. The transport port 20 is provided to transport a sample stage 30 on which a sample SAM is mounted from an outside to the inside of the lens barrel 2 or from the inside to the outside of the lens barrel 2.

When the sample SAM is analyzed, the inside of the lens barrel 2 is in a vacuum state. In the sample stage 30, a transport rod 31 is placed outside the lens barrel 2. After inserting the sample stage 30 and the transport rod 31 into the sample exchange chamber 22, the inside of the sample exchange chamber 22 is evacuated to a vacuum state using a vacuum evacuation means (not illustrated). Next, the gate valve 21 is opened, and the sample stage 30 and the transport rod 31 are transported into the lens barrel 2 through the transport port 20. The transported sample stage 30 is mounted on the stage 40. Next, the transport rod 31 is separated from the sample stage 30 and is retracted to the outside of the lens barrel 2.

The electron beam EB1 emitted from the electron gun 3 is extracted, focused, and accelerated by the suppression electrode 5, the extraction electrode 6, and the positive electrode 7, and is emitted in a direction of the optical axis OA. For example, the electron beam EB1 emitted from the electron gun 3 is expanded, contracted, and deflected by the focusing lens 9, the deflection lens 10, and the objective lens 11 including the upper magnetic pole 11a and the lower magnetic pole 11b, is confined to an irradiation region, and is emitted to the sample SAM mounted on the sample stage 30.

Signal electrons EB2 are generated from the sample SAM to which the electron beam EB1 is emitted. The generated signal electrons EB2 are detected by the detector 12. The signal electrons EB2 are, for example, secondary electrons or backscattered electrons.

A part of the electron beam EB1 emitted to the sample SAM transmits through the sample SAM as the transmitted electrons EB3. The transmitted electrons EB3 are expanded and contracted by the imaging system 13 and are emitted to the fluorescent screen 14. A fluorescence FL is generated from the fluorescent screen 14 to which the transmitted electrons EB3 are emitted. The generated fluorescence FL is detected by the camera 15.

The X-ray detectors 50 can detect an X-ray, and can detect a characteristic X-ray XL generated from the sample SAM to which the electron beam EB1 is emitted. By using energy dispersive X-ray spectrometry (EDX) based on the detected characteristic X-ray XL, elemental analysis of the sample SAM is executed. Although the details will be described below, a plurality of the X-ray detectors 50 are provided in the first embodiment.

The charged particle beam apparatus 1 includes a total control unit C0. The total control unit C0 is electrically connected to an electron source control unit C1, an electron optical system control unit C2, a stage control unit C3, a signal control unit C4, and an elemental analysis control unit C5, and supervises the control units C1 to C5. Accordingly, in some cases, the present application will be described assuming that a control that is executed by each of the control units C1 to C5 is executed by the total control unit C0. In addition, the total control unit C0 including the control units C1 to C5 will be considered one control unit, and the total control unit C0 may also be simply referred to as “control unit”.

In addition, the total control unit C0 is electrically connected to an input apparatus 16 such as a mouse or a keyboard and a monitor 17. A user can input an instruction to the total control unit C0 using the input apparatus 16, and each of operations that are executed by the total control unit C0 can be checked on the monitor 17.

The electron source control unit C1 is electrically connected to the electron source 4, and controls an operation of the electron source 4 based on the instruction from the total control unit C0.

The electron optical system control unit C2 is electrically connected to the suppression electrode 5, the extraction electrode 6, the focusing lens 9, the deflection lens 10, the objective lens coil 11c of the objective lens 11, and the imaging system 13, and controls operations thereof based on an instruction from the total control unit C0.

The stage control unit C3 is electrically connected to the stage 40 through a driving mechanism 41, and controls an operation of the stage 40 based on an instruction from the total control unit C0.

The signal control unit C4 is electrically connected to the detector 12 and the camera 15, and controls operations thereof based on an instruction from the total control unit C0. The signal control unit C4 can process, as electron information, the signal electrons EB2 detected by the detector 12 and the fluorescence FL detected by the camera 15. The electron information is converted into image data as a captured image, and the converted image data can be checked on the monitor 17 and is recorded in a recording device provided in the total control unit C0.

The elemental analysis control unit C5 is electrically connected to the X-ray detectors 50, and controls operations of the X-ray detectors 50 based on an instruction from the total control unit C0. The elemental analysis control unit C5 detects the characteristic X-ray XL generated from the sample SAM, and executes the elemental analysis of the sample SAM based on the characteristic X-ray XL. Information about the elemental analysis can be checked on the monitor 17 and is recorded in the recording device in the total control unit C0. In addition, the elemental analysis control unit C5 is also electrically connected to a moving mechanism 51 for moving the X-ray detectors 50, and controls an operation of the moving mechanism 51.

The sample SAM in the first embodiment is a thin slice sample acquired from a part of a semiconductor wafer. The semiconductor wafer is configured by, for example, a semiconductor substrate where a p-type or an n-type impurity region is formed, a semiconductor element such as a transistor formed on the semiconductor substrate, and a wiring layer formed on the semiconductor element. In addition, the state of the semiconductor wafer may include a state of only the semiconductor substrate, may include a state where the semiconductor element, the wiring layer, and the like are completed on the semiconductor substrate, and may include a state where the semiconductor element, the wiring layer, and the like are in the manufacturing process. The sample SAM is a thin slice acquired from a part of the semiconductor wafer. Therefore, the sample SAM includes some or all of the semiconductor substrate, the semiconductor element, and the wiring layer. In addition, the sample SAM may also be a structure used in a technique other than a semiconductor technique.

### <Configurations of Stage 40 and X-Ray Detectors 50>

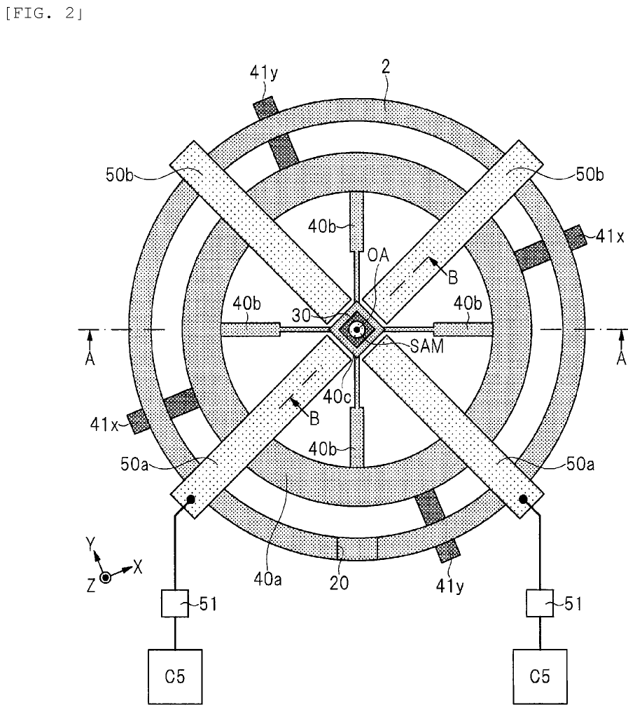

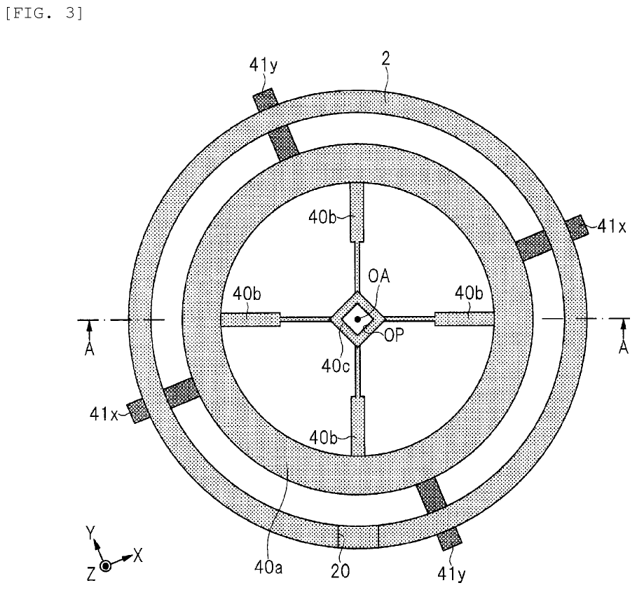

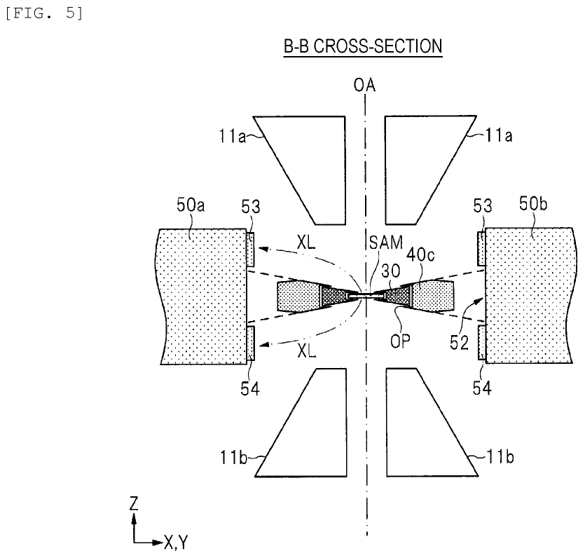

Hereinafter, a detailed structure of the stage 40 and the X-ray detectors 50 will be described using FIGS. 2 to 5. FIG. 2 is a plan view illustrating the stage 40 and the plurality of X-ray detectors 50 provided around the stage 40. FIG. 3 is a plan view illustrating only the stage 40 in FIG. 2. FIG. 4A is a cross-sectional view taken along line A-A illustrated in FIGS. 2 and 3, and is a cross-sectional view illustrating the stage 40. FIG. 4B is a cross-sectional view taken along line A-A illustrated in FIGS. 2 and 3, and is a cross-sectional view illustrating the details of the objective lens 11. FIG. 5 is a cross-sectional view taken along line B-B illustrated in FIG. 2, and is a cross-sectional view illustrating two X-ray detectors 50.

As illustrated in FIGS. 2, 3, and 4A, the stage 40 includes a peripheral portion 40a, a support portion 40b, and a mounting portion 40c. The peripheral portion 40a is connected to the lens barrel 2 through the driving mechanism 41. In addition, a planar shape of the peripheral portion 40a is annular, and the center of the annulus of the peripheral portion 40a substantially matches the optical axis OA. “Annulus” described in the present application may be substantially the same as a mathematical annulus, and does not need to be completely the same as the mathematical annulus. For example, an annulus having a notch in a part of an outer diameter or an inner diameter is also included in “annulus” described in the present application.

The mounting portion 40c is provided to mount the sample stage 30 and is provided below the electron gun 3 in the lens barrel 2. The mounting portion 40c includes at least an opening portion OP that is formed to open on the optical axis OA. In the vicinity of the opening portion OP, the mounting portion 40c holds the sample stage 30 such that an outer periphery of the sample stage 30 is interposed therein. An opening portion is also provided in the sample stage 30 in the first embodiment. In the vicinity of the opening portion, the sample stage 30 holds the sample SAM such that an outer periphery of the sample SAM is interposed therein.

When the sample stage 30 is mounted on the mounting portion 40c, the sample SAM is positioned inside the opening portion OP to be positioned on the optical axis OA. Therefore, when the electron beam EB1 is emitted from the electron gun 3 along the optical axis OA, the signal electrons EB2 are generated from the sample SAM, and a part of the electron beam EB1 transmits through the sample SAM as the transmitted electrons EB3.

The support portion 40b extends from the peripheral portion 40a toward the mounting portion 40c. One end portion of the support portion 40b is connected to the peripheral portion 40a, and the other end portion of the support portion 40b is connected to the mounting portion 40c.

Here, a plurality of the support portions 40b are provided. For example, a case where four support portions 40b are provided is illustrated. However, the mounting portion 40c only needs to be stably supported. Therefore, the number of the support portions 40b can be appropriately changed and only needs to be one or more. For example, by removing the support portion 40b closest to the transport port 20, the mounting portion 40c may be supported by the other three support portions 40b. In addition, the mounting portion 40c may be supported by two support portions 40b present on the right and left sides in the drawing.

The driving mechanism 41 is mainly formed of four driving mechanisms and, here, includes an X-axis micromotion mechanism 41x, a Y-axis micromotion mechanism 41y, a Z-axis micromotion mechanism 41z, and a tilt mechanism 41t. The X-axis micromotion mechanism 41x is connected to the peripheral portion 40a and the lens barrel 2, and is used for moving the peripheral portion 40a in the X direction. The Y-axis micromotion mechanism 41y is connected to the peripheral portion 40a and the lens barrel 2, and is used for moving the peripheral portion 40a in the Y direction. When the sample SAM is analyzed, the observation field of view of the sample SAM can be changed by driving the X-axis micromotion mechanism 41x and the Y-axis micromotion mechanism 41y.

The Z-axis micromotion mechanism 41z is connected to the peripheral portion 40a, and is used for moving the peripheral portion 40a in the Z direction. When the sample SAM is analyzed, by driving the Z-axis micromotion mechanism 41z, focusing or a working distance from the sample SAM can be adjusted. The tilt mechanism 41t is built in the mounting portion 40c, and is used for tilting the sample stage 30. When the sample SAM is analyzed, by driving the tilt mechanism 41t, an incidence angle of the electron beam EB1 on the sample SAM can be changed.

In the first embodiment, the plurality of X-ray detectors 50 are provided, and four X-ray detectors 50 are provided. The plurality of X-ray detectors 50 can execute EDX analysis. In the EDX analysis, when the electron beam EB1 is emitted to the sample SAM, the characteristic X-ray XL generated from the sample SAM is detected, and the composition analysis of the sample SAM is executed from the detected characteristic X-ray XL.

The moving mechanism 51 is electrically connected to an X-ray detector 50a closest to the transport port 20 among the plurality of X-ray detectors 50. The X-ray detector 50a is movable by the moving mechanism 51 in a direction toward or away from the mounting portion 40c (optical axis OA).

In addition, a position of an X-ray detector 50b that is positioned farther from the transport port 20 than the X-ray detector 50a among the plurality of X-ray detectors 50 is fixed. That is, the moving mechanism 51 is not electrically connected to the X-ray detector 50b. Here, a case where two X-ray detectors 50a and two X-ray detectors 50b are provided will be described as an example.

Each of the plurality of X-ray detectors 50a and 50b is attached to the lens barrel 2 independently from the stage 40. As illustrated in FIG. 2, there is a portion where the plurality of X-ray detectors 50a and 50b and the peripheral portion 40a of the stage 40 intersect with each other in a plan view. That is, there is a portion where the plurality of X-ray detectors 50a and 50b cover the peripheral portion 40a in a cross-sectional view. Although the details are not illustrated, in a part of the peripheral portion 40a, a passage such as a hole or a notch is provided such that the plurality of X-ray detectors 50a and 50b can pass through the passage.

The plurality of X-ray detectors 50a and 50b have such a structure. Therefore, the support portion 40b of the stage 40 is disposed in a space where the plurality of X-ray detectors 50a and 50b are not provided. That is, the plurality of X-ray detectors 50a and 50b are provided at positions not overlapping the mounting portion 40c and the support portion 40b in a plan view.

Incidentally, as illustrated in FIGS. 4A and 5, cross-sectional shapes of the sample stage 30 and the mounting portion 40c are substantially triangular, and the thicknesses of the sample stage 30 and the mounting portion 40c increase in a direction away from the sample SAM. Due to such a shape, the characteristic X-ray XL generated from the sample SAM is not likely to be shielded by the sample stage 30 and the mounting portion 40c, and is likely to be detected by the plurality of X-ray detectors 50a and 50b.

However, as illustrated in FIG. 5, a shielded region 52 where it is difficult to detect the characteristic X-ray XL is present in the plurality of X-ray detectors 50a and 50b. Therefore, in a region other than the shielded region 52, it is necessary to detect the characteristic X-ray XL with high sensitivity. Accordingly, each of the plurality of X-ray detectors 50a and 50b includes an upper sensor 53 for detecting the characteristic X-ray XL generated from an upper surface side of the sample SAM and a lower sensor 54 for detecting the characteristic X-ray XL generated from a lower surface side of the sample SAM. The characteristic X-ray XL can be detected from both of an incidence side and a transmission side of the electron beam EB1. Therefore, the detection sensitivity can be improved.

When the thickness of the sample SAM is large, the amount of the characteristic X-ray XL generated from the lower surface side of the sample SAM may be small. Therefore, among the upper sensor 53 and the lower sensor 54, it is preferable that at least the upper sensor 53 is provided. In addition, here, a case where the plurality of X-ray detectors 50a and 50b are provided to cover the peripheral portion 40a of the stage 40 is described as an example. However, the plurality of X-ray detectors 50a and 50b may be provided only above the stage 40 without interfering with the peripheral portion 40a. As a result, the characteristic X-ray XL generated from at least the upper surface side of the sample SAM can be detected.

FIG. 4B is a cross-sectional view illustrating the details of the objective lens 11. The upper magnetic pole 11a and the lower magnetic pole 11b are connected through a magnetic path 42, and the objective lens coil 11c that is provided below the objective lens 11 is surrounded by the magnetic path 42. As a result, a magnetic field is formed between the upper magnetic pole 11a and the lower magnetic pole 11b. The magnetic path 42, the stage 40, and the X-ray detectors 50 are disposed not to interfere with each other, and are supported by or connected to the lens barrel 2 or the like, respectively.

FIG. 4C is a cross-sectional view illustrating a modification example of the stage 40, and is an explanatory diagram illustrating a tilt mechanism of the stage 40 having two axes. In FIG. 4A, the tilt mechanism has one axis due to the tilt mechanism 41t provided in the mounting portion 40c. FIG. 4C illustrates the modification example where the tilt mechanism has two axes. The stage 40 of FIG. 4C includes the tilt mechanism 41t and a rotation mechanism 41a. The tilt mechanism 41t provided in the mounting portion 40c of FIG. 4A is changed to the rotation mechanism 41a. The rotation mechanism 41a rotates the sample SAM on a horizontal plane to change the azimuth angle. The tilt mechanism 41t is provided on a base of the support portion 40b of FIG. 4C, and the tilt mechanism 41t rotates the support portion 40b with a motor or the like. The tilt mechanism 41t tilts the sample SAM with respect to the optical axis OA to change the tilt angle.

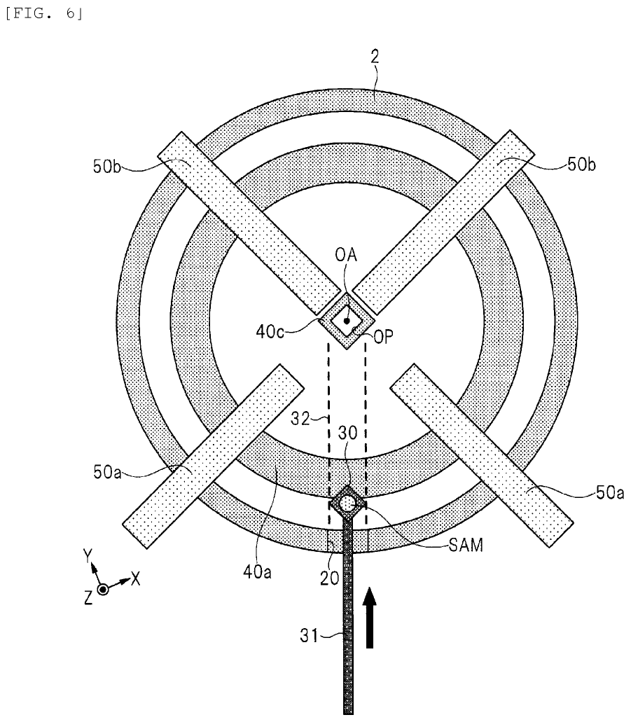

FIGS. 6 to 8 illustrate, as a part of an analysis method of the sample SAM, a transport method of transporting the sample SAM from the outside to the inside of the lens barrel 2. In order to simplify the drawings, FIGS. 6 to 8 illustrate only the peripheral portion 40a and the mounting portion 40c among the members relating to the stage 40.

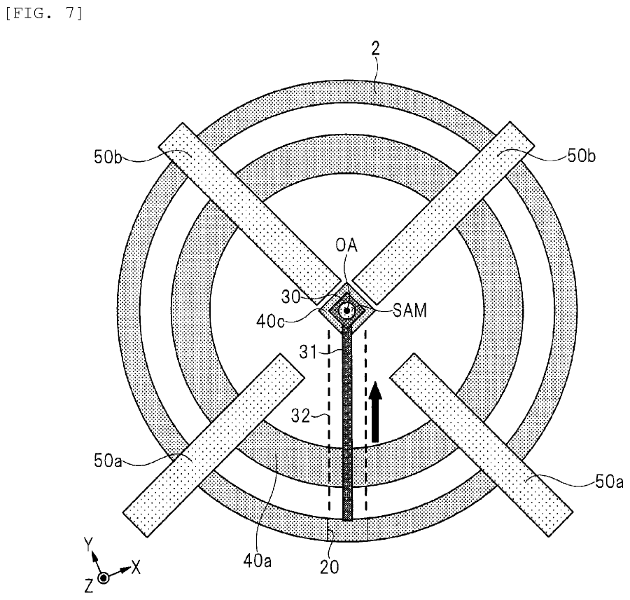

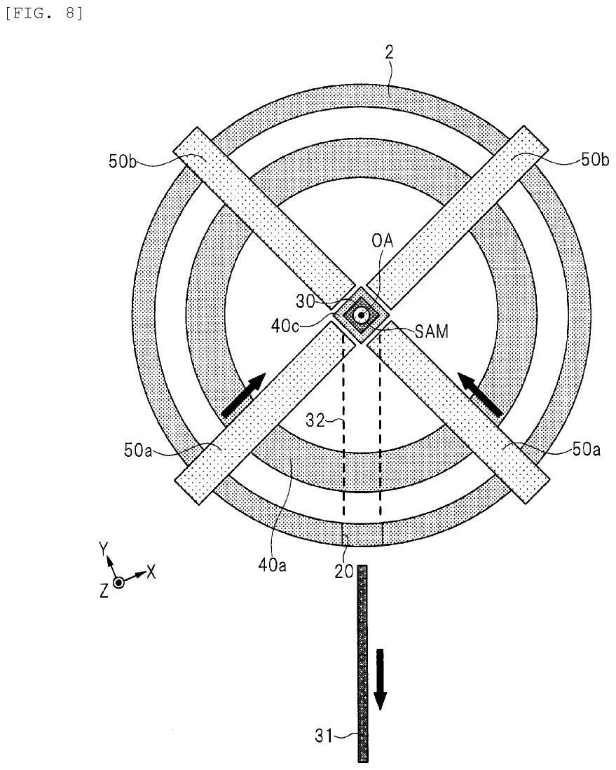

As illustrated in FIG. 6, first, the sample stage 30 on which the sample SAM is mounted is placed on the transport rod 31. Next, the transport rod 31 is inserted into the lens barrel 2 from the outside of the lens barrel 2 through the transport port 20. Here, the X-ray detector 50a positioned close to the transport port 20 is moved away from the mounting portion 40c. Next, as illustrated in FIG. 7, by further inserting the transport rod 31, the sample stage 30 is mounted on the mounting portion 40c. Next, as illustrated in FIG. 8, the transport rod 31 is separated from the sample stage 30, and the transport rod 31 is retracted from the inside to the outside of the lens barrel 2 through the transport port 20.

Next, the X-ray detector 50a moves toward the mounting portion 40c. The sample SAM is analyzed by emitting the electron beam EB1 from the electron gun 3 along the optical axis OA in a state where the X-ray detector 50a is moved close to the mounting portion 40c and detecting the characteristic X-ray XL generated from the sample SAM to which the electron beam EB1 is emitted with the plurality of X-ray detectors 50a and 50b.

When the analysis of the sample SAM ends and the sample SAM is transported from the inside to the outside of the lens barrel 2, the procedure may be executed in the reverse order. That is, first, the X-ray detector 50a is moved away from the mounting portion 40c. Next, the transport rod 31 is inserted into the lens barrel 2 from the outside of the lens barrel 2 through the transport port 20. Next, the sample stage 30 on which the sample SAM is mounted is placed on the transport rod 31. Next, the transport rod 31 is retracted from the inside to the outside of the lens barrel 2 through the transport port 20.

### Main Effect of First Embodiment

A transport path 32 illustrated in FIGS. 6 to 8 is a path through which the sample stage 30 passes from the transport port 20 to the mounting portion 40c. Here, as illustrated in FIG. 8, a position of the X-ray detector 50a when the X-ray detector 50a is moved closest to the mounting portion 40c overlaps the transport path 32 in a plan view.

As described in the above-described problem, the sample holder inserted into the lens barrel is used in the related art. Therefore, there is a problem in that, in the space where the sample holder is present, the X-ray detector cannot be provided. Accordingly, it is difficult to improve the detection sensitivity of an X-ray, for example, using a method of increasing the number of X-ray detectors or moving the sample toward the X-ray detector.

On the other hand, in the first embodiment, the sample holder is not used. When the sample stage 30 is transported, the X-ray detector 50a is moved away from the mounting portion 40c. When the sample SAM is analyzed, the X-ray detector 50a is moved close up to a position overlapping the transport path 32. In other words, in the space where the sample holder is present in the related art, the X-ray detector 50a can be provided. Accordingly, in the first embodiment, an X-ray can be detected with high sensitivity.

The X-ray detector 50b positioned away from the transport port 20 is originally positioned close to the mounting portion 40c. When the sample SAM is analyzed, the X-ray detector 50a is also positioned close to the mounting portion 40c to the same degree as the X-ray detector 50b. That is, a distance between a tip portion of the X-ray detector 50b and the mounting portion 40c is the same as a distance between a tip portion of the X-ray detector 50a when the X-ray detector 50a is moved closest to the mounting portion 40c and the mounting portion 40c. Accordingly, an X-ray can be detected with high sensitivity by the plurality of X-ray detectors 50a and 50b.

In addition, in the related art, the portion on the atmospheric pressure side of the sample holder is affected by an air pressure variation, a sonic wave, and the like, and thus displacement of the field of view may occur. On the other hand, in the first embodiment, when the sample SAM is analyzed, the sample stage 30 is typically disposed in the lens barrel 2 (vacuum side), and the portion on the atmospheric pressure side is not present. Accordingly, the above-described problem such as the displacement of the field of view does not occur, and thus the stability and the accuracy of the analysis of the sample SAM can be improved.

Incidentally, an outer peripheral shape of the mounting portion 40c in a plan view is polygonal, and is quadrangular in the first embodiment. A tip portion of each of the plurality of X-ray detectors 50a and 50b faces each of sides of the mounting portion 40c in a plan view. A position facing each of the sides of the mounting portion 40c is a position closest to the mounting portion 40c. By disposing the plurality of X-ray detectors 50a and 50b as described above, the sensitivity for detecting an X-ray can be further improved. The number of the plurality of X-ray detectors 50a and 50b is the same as the number of the sides of the mounting portion 40c in a plan view. In addition, the other end portion of the support portion 40b supports any of corners of the mounting portion 40c in a plan view not to inhibit the disposition of the plurality of X-ray detectors 50a and 50b.

In addition, it is preferable that any of the corners of the mounting portion 40c in a plan view faces the transport port 20. When one side of the mounting portion 40c faces the transport port 20, it is difficult to dispose the X-ray detector 50 at a position facing the side. In this case, the number of the X-ray detectors 50 is reduced, and the sensitivity for detecting an X-ray may decrease.

In the first embodiment, the two X-ray detectors 50a and the two X-ray detectors 50b that are line-symmetric with respect to the transport port 20 are provided. However, a position where the plurality of X-ray detectors 50 are disposed is not limited to this configuration. For example, referring to FIG. 2, the transport port 20 may be provided close to the right X-ray detector 50a. In this case, the moving mechanism 51 is electrically connected to the right X-ray detector 50a closest to the transport port 20. However, the moving mechanism 51 may also be electrically connected to the left X-ray detector 50a, which is the second closest to the transport port 20, if necessary. In other words, the moving mechanism 51 is electrically connected to the X-ray detector 50 that is likely to overlap the transport path 32 in a plan view.

In addition, when the support portion 40b disposed on the transport port 20 side among the plurality of support portions 40b interferes with the transport path 32 in a plan view, the support portion 40b may be connected to the peripheral portion 40a below the transport path 32 to support the mounting portion 40c from below in a longitudinal section. In addition, the support portion 40b close to the transport port 20 may be shifted and disposed not to overlap the transport path 32 in a plan view.

### First Modification Example

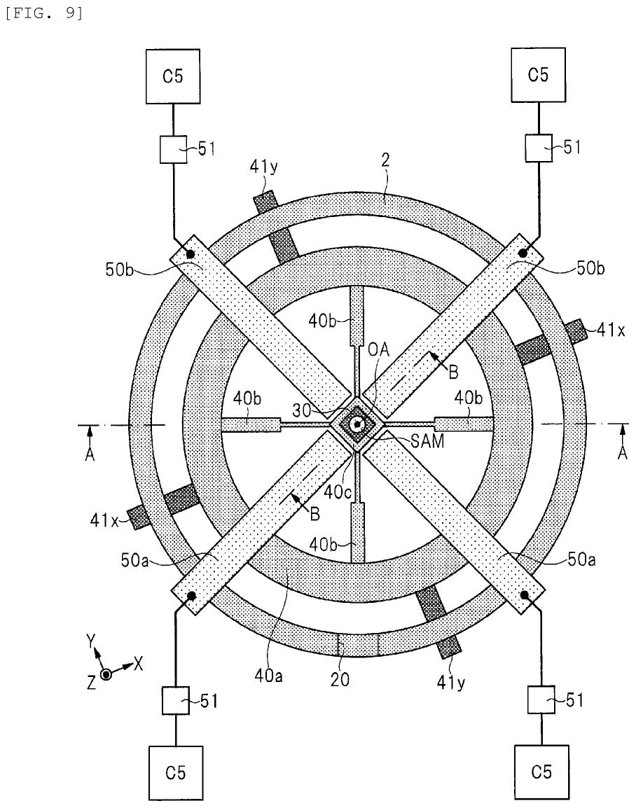

Hereinafter, the charged particle beam apparatus 1 according to a first modification example will be described using FIG. 9. Hereinafter, a difference from the first embodiment will be mainly described, and the description of the same points as the first embodiment will not be repeated.

In the first embodiment, the position of the X-ray detector 50b is fixed. As illustrated in FIG. 9, in the first modification example, the moving mechanism 51 is also electrically connected to the X-ray detector 50b, and the position of the X-ray detector 50b can be changed. The X-ray detector 50b is movable by the moving mechanism 51 in a direction toward or away from the mounting portion 40c.

By allowing all of the plurality of X-ray detectors 50 to be movable, the plurality of X-ray detectors 50 can be retracted from the vicinity of the electron beam EB1, for example, in an analysis step where analysis using an X-ray is unnecessary. As a result, a period of time during which the upper sensor 53, the lower sensor 54, and the like are exposed to the signal electrons EB2 (secondary electrons or backscattered electrons) can be reduced. Therefore, the frequency of maintenance such as replacement of a sensor can be reduced.

### Second Modification Example

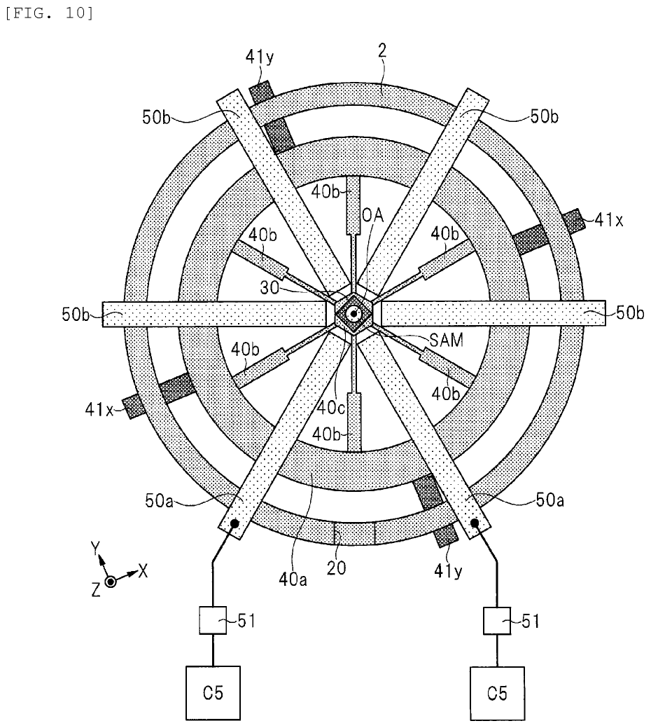

Hereinafter, the charged particle beam apparatus 1 according to a second modification example will be described using FIG. 10. Hereinafter, a difference from the first embodiment will be mainly described, and the description of the same points as the first embodiment will not be repeated.

As illustrated in FIG. 10, in the second modification example, two X-ray detectors 50a and four X-ray detectors 50b are provided. By increasing the number of the X-ray detectors 50, the sensitivity for detecting an X-ray can be further improved.

In addition, an outer peripheral shape of the mounting portion 40c in a plan view is polygonal and is hexagonal in the second modification example. In the second modification example, likewise, a tip portion of each of the plurality of X-ray detectors 50a and 50b faces each of sides of the mounting portion 40c in a plan view, and the number of the plurality of X-ray detectors 50a and 50b is the same as the number of the sides of the mounting portion 40c in a plan view.

This way, the number of the plurality of X-ray detectors 50 is not particularly limited and is preferably at least three or more. Even in the second modification example, as in the first modification example, the moving mechanism 51 is connected to all of the X-ray detectors 50.

### <Sample Analysis Method>

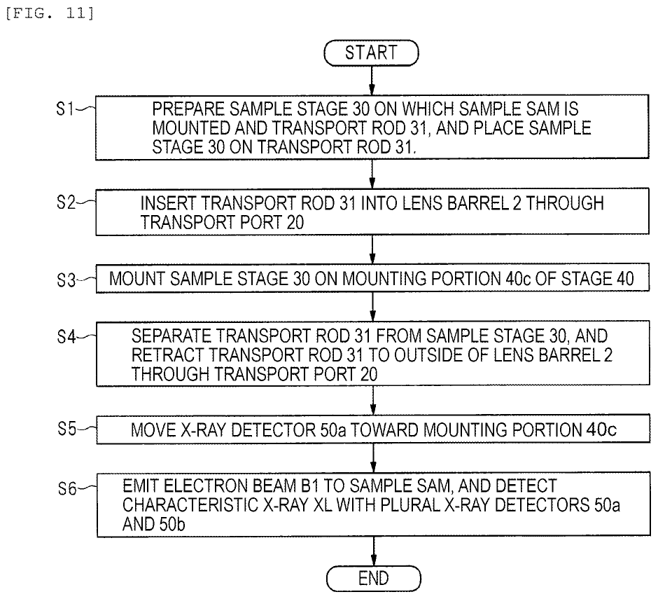

Hereinafter, an analysis method of the sample SAM according to the first embodiment, the first modification example, and the second modification example will be described using a flowchart of FIG. 11 and FIGS. 6 to 8.

First, in Step S1, the sample stage 30 on which the sample SAM is mounted and the transport rod 31 are prepared. Next, the sample stage 30 is placed on the transport rod 31. At this time, the inside of the lens barrel 2 is in a vacuum state.

In Step S2, in a state where the X-ray detector 50a is moved away from the mounting portion 40c, the transport rod 31 on which the sample stage 30 is placed is inserted into the lens barrel 2 from the outside of the lens barrel 2 through the transport port 20. First, the transport rod 31 and the sample stage 30 are inserted into the sample exchange chamber 22 from the outside of the lens barrel 2. Next, an inside of the sample exchange chamber 22 is in a vacuum state to the same degree as the inside of the lens barrel 2. Next, the gate valve 21 is opened, and the transport rod 31 is inserted into the lens barrel 2 from the inside of the sample exchange chamber 22 through the transport port 20.

In Step S3, the sample stage 30 is mounted on the mounting portion 40c such that the sample SAM is positioned on the optical axis OA.

In Step S4, the transport rod 31 is separated from the sample stage 30, and the transport rod 31 is retracted from the inside to the outside of the lens barrel 2 through the transport port 20. The transport rod 31 may be retracted to the outside of the lens barrel 2. However, as long as the transport rod 31 can be retracted up to a position not interfering with the X-ray detectors 50, a part of the transport rod 31 may remain in the lens barrel 2. Next, Step S5 is executed. In this case, screening of the sample SAM may be executed before Step S5.

For example, the electron beam EB1 is emitted to the sample SAM, the signal electrons EB2 generated from the sample SAM are detected by the detector 12, and a captured image created based on the signal electrons EB2 is observed. Alternatively, the characteristic X-ray XL generated from the sample SAM is detected by the X-ray detector 50b, and the elemental analysis of the sample SAM is executed. At this time, when the sample SAM is largely broken or when an element that is clearly different from an assumed element is detected, the determination of the screening is a failure. The sample SAM that is determined as a failure is discarded, and another sample SAM is newly transported to the inside of the lens barrel 2. On the other hand, Step S5 and the subsequent steps are executed only on the sample SAM that is determined as pass in the determination of the screening.

In Step S5, the X-ray detector 50a is moved toward the mounting portion 40c. As a result, all of the X-ray detectors 50a and 50b are disposed close to the mounting portion 40c. Therefore, the characteristic X-ray XL of the sample SAM can be detected with high sensitivity.

In Step S6, the electron beam EB1 is emitted from the electron gun 3 along the optical axis OA. The characteristic X-ray XL generated from the sample SAM when the electron beam EB1 is emitted to the sample SAM is detected with the plurality of X-ray detectors 50a and 50b. As a result, the elemental analysis of the sample SAM is executed.

In addition, the analysis step that is executed by emitting the electron beam EB1 to the sample SAM may be executed. For example, the signal electrons EB2 may be detected with the detector 12, the fluorescence FL may be detected with the camera 15, the detected signal electrons EB2 and the fluorescence FL may be processed as electron information by the signal control unit C4, and image data may be acquired based on the electron information.

Here, as in the first modification example, when the moving mechanism 51 is electrically connected to all of the X-ray detectors 50a and 50b, as in the analysis step, the steps other than the step of detecting the characteristic X-ray XL are executed in a state where all of the plurality of X-ray detectors 50a and 50b are moved away from the mounting portion 40c.

When the analysis of the sample SAM ends, the sample SAM is transported from the inside to the outside of the lens barrel 2. First, the X-ray detector 50a is moved away from the mounting portion 40c. Next, the transport rod 31 is inserted into the lens barrel 2 from the outside of the lens barrel 2 through the transport port 20. Next, the sample stage 30 on which the sample SAM is mounted is placed on the transport rod 31. Next, the transport rod 31 is retracted from the inside to the outside of the lens barrel 2 through the transport port 20.

Hereinabove, the present invention has been described in detail based on the embodiment. However, the present invention is not limited to the embodiment, and various modifications can be made within a range not departing from the scope of the present invention.

For example, in the above-described embodiment, the case where energy dispersive X-ray spectrometry (EDX) is used for analyzing the characteristic X-ray XL has been described. However, wavelength-dispersive X-ray spectroscopy (WDX) may be used for analyzing the characteristic X-ray XL.

### REFERENCE SIGNS LIST

1: charged particle beam apparatus
2: lens barrel
3: electron gun
4: electron source
5: suppression electrode
6: extraction electrode
7: positive electrode
8: electron optical system
9: focusing lens
10: deflection lens
11: objective lens
11a: upper magnetic pole
11b: lower magnetic pole
11c: objective lens coil
12: detector
13: imaging system
14: fluorescent screen
15: camera
16: input apparatus
17: monitor
18: STEM detector
20: transport port
21: gate valve
22: sample exchange chamber
30: sample stage
31: transport rod
32: transport path
40: stage
40a: peripheral portion
40b: support portion
40c: mounting portion
41: driving mechanism
41a: rotation mechanism
41t: tilt mechanism
41x: X-axis micromotion mechanism
41y: Y-axis micromotion mechanism
41z: Z-axis micromotion mechanism
42: magnetic path
50, 50a, 50b: X-ray detector
51: moving mechanism
52: shielded region
53: upper sensor
54: lower sensor
C0: total control unit (control unit)
C1: electron source control unit
C2: electron optical system control unit
C3: stage control unit
C4: signal control unit
C5: elemental analysis control unit
EB1: electron beam
EB2: signal electron
EB3: transmitted electron
FL: fluorescence
OA: optical axis
OP: opening portion
SAM: sample
XL: characteristic X-ray

1. A charged particle beam apparatus comprising:
a lens barrel;
an electron gun configured to emit an electron beam and provided in the lens barrel;
a stage provided in the lens barrel;
a transport port provided in the lens barrel to transport a sample stage on which a sample is mounted from an outside to an inside of the lens barrel or from the inside to the outside of the lens barrel; and
a plurality of X-ray detectors configured to detect an X-ray and provided in the lens barrel, wherein
the stage includes a mounting portion that is provided to mount the sample stage and is provided below the electron gun in the lens barrel,
the mounting portion includes at least an opening portion that is formed to open on an optical axis,
when the sample stage is mounted on the mounting portion, the sample is positioned in the opening portion to be positioned on the optical axis,
a moving mechanism is electrically connected to a first X-ray detector closest to the transport port among the plurality of X-ray detectors,
the first X-ray detector is movable by the moving mechanism in a direction toward or away from the mounting portion, and
a position of the first X-ray detector when the first X-ray detector is moved closest to the mounting portion overlaps a transport path through which the sample stage passes from the transport port to the mounting portion in a plan view.

2. The charged particle beam apparatus according to claim 1, wherein the transport of the sample stage from the outside to the inside of the lens barrel or from the inside to the outside of the lens barrel is executed in a state where the first X-ray detector is moved away from the mounting portion.

3. The charged particle beam apparatus according to claim 2, wherein the sample is analyzed by emitting the electron beam from the electron gun along the optical axis in a state where the first X-ray detector is moved close to the mounting portion and detecting a characteristic X-ray generated from the sample to which the electron beam is emitted with the plurality of X-ray detectors.

4. The charged particle beam apparatus according to claim 3, wherein each of the plurality of X-ray detectors includes a first sensor for detecting the characteristic X-ray generated from an upper surface side of the sample and a second sensor for detecting the characteristic X-ray generated from a lower surface side of the sample.

5. The charged particle beam apparatus according to claim 1, wherein
the stage further includes a peripheral portion of which a planar shape is annular and a support portion extending from the peripheral portion to the mounting portion, wherein
the peripheral portion is connected to the lens barrel,
one end portion of the support portion is connected to the peripheral portion, and
the other end portion of the support portion is connected to the mounting portion.

6. The charged particle beam apparatus according to claim 5, wherein the plurality of X-ray detectors are provided at a position not overlapping the mounting portion and the support portion in a plan view.

7. The charged particle beam apparatus according to claim 6, wherein
an outer peripheral shape of the mounting portion in a plan view is polygonal,
a tip portion of each of the plurality of X-ray detectors faces each of sides of the mounting portion in a plan view, and
the other end portion of the support portion supports any of corners of the mounting portion in a plan view.

8. The charged particle beam apparatus according to claim 7, wherein the number of the plurality of X-ray detectors is the same as the number of the sides of the mounting portion in a plan view.

9. The charged particle beam apparatus according to claim 7, wherein any of the corners of the mounting portion in a plan view faces the transport port.

10. The charged particle beam apparatus according to claim 1, wherein
a position of a second X-ray detector that is positioned farther from the transport port than the first X-ray detector among the plurality of X-ray detectors is fixed, and
a distance between a tip portion of the second X-ray detector and the mounting portion is the same as a distance between a tip portion of the first X-ray detector when the first X-ray detector is moved closest to the mounting portion and the mounting portion.

11. The charged particle beam apparatus according to claim 1, wherein
the moving mechanism is electrically connected to the second X-ray detector that is positioned farther from the transport port than the first X-ray detector among the plurality of X-ray detectors, and
the second X-ray detector is movable by the moving mechanism in a direction toward or away from the mounting portion.

12. A sample analysis method that is executed using the charged particle beam apparatus according to claim 1, the sample analysis method comprising:
(a) a step of preparing the sample stage on which the sample is mounted and a transport rod;
(b) a step of placing the sample stage on the transport rod after the step (a);
(c) a step of inserting the transport rod into the lens barrel from the outside of the lens barrel through the transport port in a state where the first X-ray detector is moved away from the mounting portion after the step (b);
(d) a step of mounting the sample stage on the mounting portion such that the sample is positioned on the optical axis after the step (c);
(e) a step of separating the transport rod from the sample stage and retracting the transport rod up to a position not interfering with the X-ray detector after the step (d);
(f) a step of moving the first X-ray detector toward the mounting portion after the step (e);
(g) a step of emitting the electron beam from the electron gun along the optical axis after the step (f); and
(h) a step of detecting, with the plurality of X-ray detectors, a characteristic X-ray generated from the sample when the electron beam is emitted to the sample after the step (g).

13. The sample analysis method according to claim 12, wherein
screening of the sample is executed between the step (e) and the step (f), and
the step (f), the step (g), and the step (h) are executed only on the sample that is determined as pass in determination of the screening.

14. The sample analysis method according to claim 12, wherein
the moving mechanism is electrically connected to all of the plurality of X-ray detectors,
all of the plurality of X-ray detectors are movable by the moving mechanism in a direction toward or away from the optical axis, and
in the analysis step that is executed by emitting the electron beam to the sample, the steps other than the step of detecting the characteristic X-ray are executed in a state where all of the plurality of X-ray detectors are moved away from the mounting portion.
